(19) United States
(12) Patent Application Publication
(10) Pub. No.: US 2019/0047818 A1
(43) Pub. Date: Feb. 14, 2019

(54) APPARATUS AND METHOD FOR GROUND FAULT DETECTION

(71) Applicant: Otis Elevator Company, Farmington, CT (US)

(72) Inventors: Peter Herkel, Berlin (DE); Dirk Tegtmeier, Berlin (DE)

(21) Appl. No.: 15/758,776

(22) PCT Filed: Sep. 10, 2015
(86) PCT No.: PCT/EP2015/070738

§ 371 Date: Mar. 9, 2018

(51) Int. Cl. B66B 5/00; G01R 31/02; B66B 13/22; G05B 19/042; G01R 19/165

(52) U.S. Cl. CPC B66B 5/0031; G01R 31/025; G05B 9/03; G05B 19/0425; G01R 19/16528; B66B 13/22

(57) ABSTRACT

A ground fault detection apparatus (32) for detecting a ground fault of a safety chain (10b; 10c; 10d), in particular a safety chain (10b; 10c; 10d) of a people conveyor, comprises: a supply line current monitoring unit (26), which is configured for measuring a current flowing into the safety chain (10b; 10c; 10d) and providing a first signal indicative of the amount of current flowing into the safety chain (10b; 10c; 10d); a return line current monitoring unit (28), which is configured for measuring a current flowing out of the safety chain (10b; 10c; 10d) and providing a second signal indicative of the amount of current flowing out of the safety chain (10b; 10c; 10d); and a comparison unit (30), which is configured for comparing the first and second signals and issuing an alarm signal in case the difference between the first and second signals exceeds a predetermined limit.

The invention relates to an apparatus and a method for detecting a ground fault of a safety chain, in particular a ground fault of a safety chain used in a people conveyor.

People conveyors such as elevators, escalators or moving walkways are equipped with a safety chain in order to ensure safe operation. A safety chain usually comprises a plurality of sequentially interconnected safety switches and/or safety circuits and is configured to stop any operation of the people conveyor in case the safety chain is interrupted by at least one of the safety switches or safety circuits. As such a safety chain is subjected to ground faults, ground fault detection is a required function for the safety chain in people conveyors, as specified e.g. in any elevator safety code worldwide.

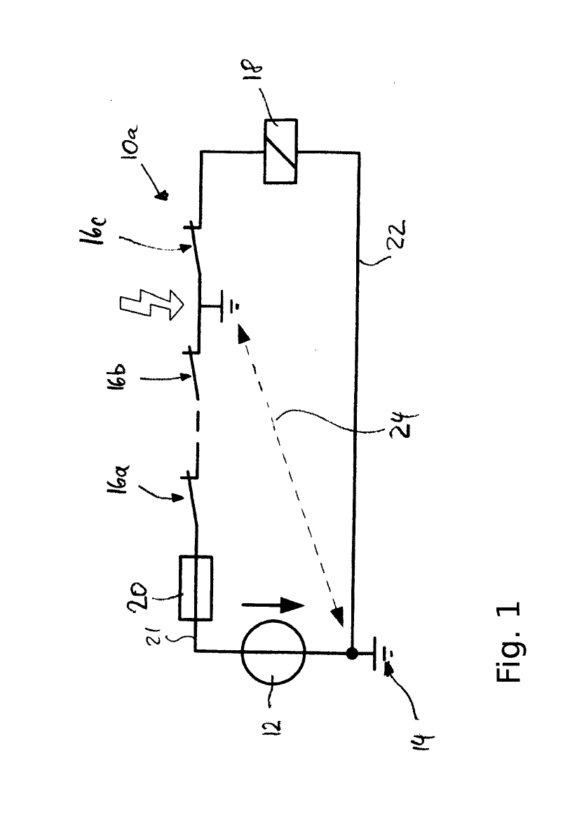

A ground fault is an unwanted connection of an electrical circuit to ground or earth. Currently, ground faults are usually detected by means of a fuse. As shown in FIG. 1, a safety chain 10a is connected between a power supply 12 and ground or earth 14. The safety chain 10a includes a plurality of safety switches 16a, 16b, 16c and a safety relay 18, all connected in series. The safety relay 18 is configured to perform the requested safety functions, i.e. to stop the motor driving the conveyor and to activate a brake. A fuse 20 is provided in the safety chain supply line 21, as shown in FIG. 1. The safety chain return 22 is connected to ground 14. When any point in the wiring of the safety chain 10a has contact to ground causing a ground fault 24, as indicated by the dashed line in FIG. 1, the current flowing through fuse 20 will increase the current threshold of the fuse 20 and the fuse 20 will blow interrupting any flow of electrical current through the safety chain.

The implementation of ground fault detection using a fuse 20, as it is shown in FIG. 1, requires that, in case of a ground fault, the power supply 12 is able to provide sufficient current to blow up the fuse 20 within a given threshold time. For example, safety code EN 60204-1 specifies a threshold time of 5 s for blowing the fuse in case of a ground fault. To safely trigger the fuse within 5 s, as requested by safety code requirements, current flowing through the fuse must exceed the threefold of the nominal current threshold of the fuse.

Standard transformers, as conventionally used for power supply in elevators, are able to deliver sufficiently high currents. However, switching-mode power supplies, as used more and more instead of transformers, usually have a current limitation and therefore may not be able to supply sufficient electric current to blow the fuse in case of a ground fault, or need to be overdimensioned in order to be able to safely blow the fuse in case of a ground fault. For example, in the safety chain shown in FIG. 1, in normal condition a current of 0.16 A is flowing in the safety chain at a safety chain supply voltage of 48 V DC. The rated current threshold for triggering the fuse 20 is 0.4 A, i.e. the fuse will not blow in case the current stays below this rated current threshold. In this example, to blow the fuse 20 within 5 s, current in the safety chain must exceed 1.2 A. Therefore, any power supply used as supply for the safety chain must be able to provide a power of 48 V DC times 1.2 A=58 W. However, in normal conditions only a power of 8 W is required. Therefore, the power supply must be significantly overdimensioned with respect normal operation requirements, in order to meet the safety code requirements with respect to ground fault protection.

Conventional safety chains 10a use electro-mechanical safety relays 18. The resistance of such safety relays 18 is relatively low. In consequence they draw a large current flowing in the safety chain 10a. As a result, conventional safety chains 10a using electro-mechanical safety relays 18 are relatively robust with respect to ground faults 24. Only relatively hard ground faults 24, i.e. ground faults 24 with a low or even basically zero resistance, have a significant impact on the safety chain 10a. A fuse 20 connected in the safety chain 10a relatively safely blows in case of occurrence of a hard ground fault 24 in a conventional safety chain 10a. In a safety chain 10a including a safety relay 18 based on printed circuit relays and/or semiconductor switches, the safety relay 18 has a much higher electrical resistance (about 2300 Ohm compared to about 300 Ohm for an electro-mechanical relay/contactor) and therefore draws much less current. As a result, such safety chain 10a is much more sensitive with respect to soft ground faults 24, i.e. ground faults 24 having a resistance in the order of several hundred Ohm. However, it is problematic to configure a fuse 20 in such a way that the fuse 20 safely blows when a soft ground fault 24 occurs.

The schematic of FIG. 1 indicates a ground fault 24 occurring somewhere in the middle of the safety chain 10a. With a hard ground fault, ground resistance will be less than 1 Ohm and the current flowing through the fuse 20 will increase to above 4 A. This will lead to blowing of the fuse. However, with soft ground fault, e.g. at a ground fault resistance slightly below 100 Ohm, existence of the ground fault will increase the current flowing through the fuse 20 slightly above its trigger current (e.g. 0.4 A) only. Although this is above the current threshold of 0.4 A for triggering the fuse 20, it will take much more time than 5 s to blow the fuse 20. Typically, in this example, the fuse 20 may take several minutes to blow. As a consequence, a soft ground fault as described above might be detected late or even not be detected at all, contrary to code requirements. In case a second ground fault occurs later both ground faults together may lead to a safety issue under certain conditions. The probability of such problems even increases where printed circuit board relays are used instead of relays/contactors, since printed circuit board relays have a higher coil resistance than mechanical relays/contactors.

Furthermore, in modern safety chain implementations, in particular when electronic safety is used, the safety chain may comprise a plurality of segments. In this case the electric current flowing in each of the segments may be so small that it is difficult to provide a well-suited fuse which will blow up within the required time period in case of a ground fault.

It therefore is desirable to improve the detection of ground faults in a safety chain. It in particular would be beneficial to overcome the above mentioned problems of conventional ground fault detection.

According to an exemplary embodiment of the invention, a ground fault detection apparatus for detecting a ground fault of a safety chain, in particular a safety chain of a people conveyor, comprises: a supply line current monitoring unit, which is located at or in the safety chain supply line and which is configured for measuring a current flowing through the safety chain supply line into the safety chain and providing a first signal indicative of the amount of current flowing into the safety chain; a return line current monitoring unit, which is located at or in the safety chain return line and which is configured for measuring a current flowing through the safety chain return line out of the safety chain and providing a second signal indicative of the amount of current flowing out of the safety chain. The ground fault detection apparatus further comprises a comparison unit which is configured for comparing the first and second signals respectively provided by the current monitoring units and for issuing an alarm signal in case the difference between the first and second signals exceeds a predetermined limit.

A method of detecting a ground fault of a safety chain, in particular a safety chain of a people conveyor, comprises the steps of:
measuring a current flowing into the safety chain and providing a first signal indicative of the amount of current flowing into the safety chain;
measuring a current flowing out of the safety chain and providing a second signal indicative of the amount of current flowing out of the safety chain;
comparing the first and second signals and issuing an alarm signal in case the difference between the first and second signals exceeds a predetermined limit.

A ground fault detection apparatus and a method for detecting a ground fault of a safety chain according to exemplary embodiments of the invention allow for a fast and reliable detection of ground faults of a safety chain. They in particular allow to reliably monitor a plurality of segments of the safety chain and to detect even small ground currents as they occur in case of soft ground faults. As a result, the safety of a people conveyor employing a safety chain is considerably enhanced.

In the following, exemplary embodiments will be described in more detail with reference to the enclosed Figures.

FIG. 1 shows a circuit diagram of a safety chain including a fuse for ground fault detection according to the prior art.

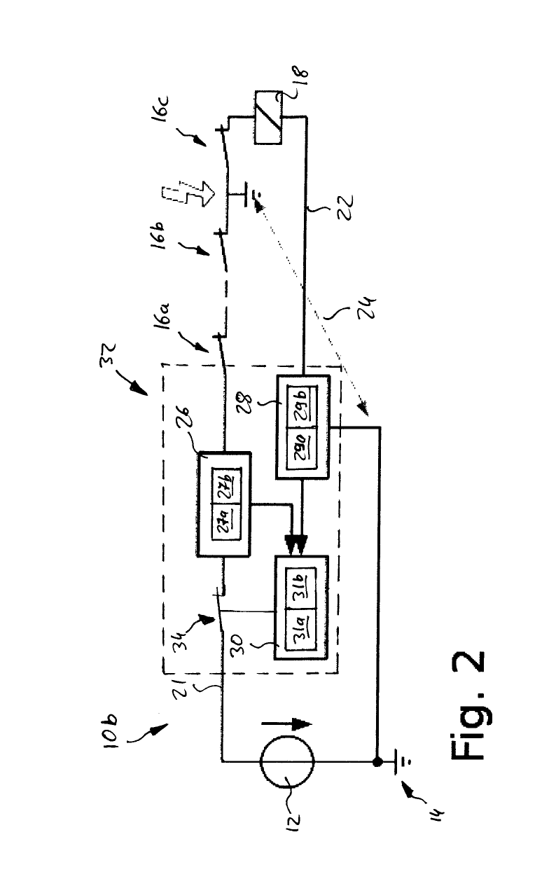

FIG. 2 shows a circuit diagram of a safety chain including a ground fault detection apparatus according to a first embodiment.

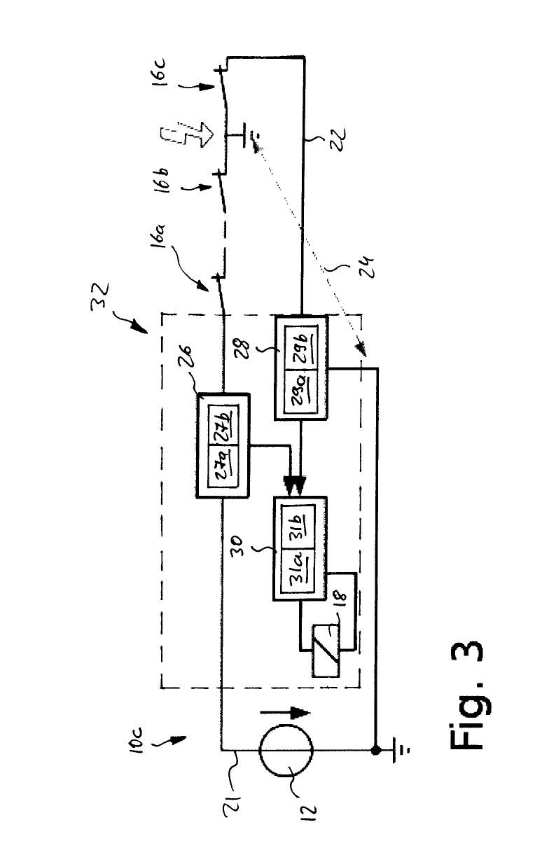

FIG. 3 shows a circuit diagram of safety chain including a ground fault detection apparatus according to another embodiment.

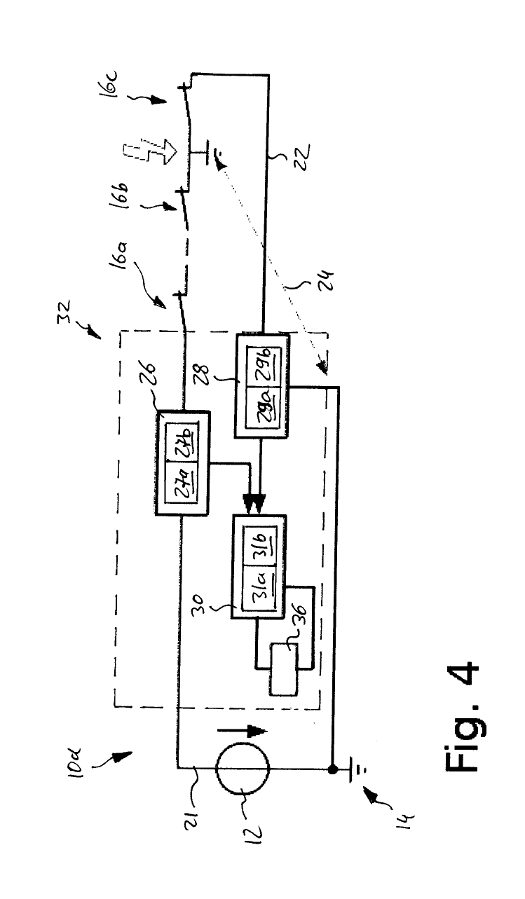

FIG. 4 shows a circuit diagram of safety chain including a ground fault detection apparatus according to yet another embodiment.

The safety chain 10b including a ground fault detection apparatus 32 according to a first embodiment, as it is illustrated in FIG. 2, is based on a conventional safety chain 10a, as it is shown in FIG. 1. The same components are denoted with the same reference signs and will not be discussed in detail again.

The ground fault detection apparatus 32 according to the first embodiment comprises a supply line current monitoring unit 26, which is configured for measuring the current flowing through the safety chain supply line 21 into the safety chain 10b and providing a first signal which is indicative of the amount of current flowing into the safety chain 10b. It further comprises a return line current monitoring unit 28, which is configured for measuring the current flowing through the safety chain return line 22 out of the safety chain 10b and providing a second signal which is indicative of the amount of current flowing into the safety chain 10b.

The supply line current monitoring unit 26 and the return line current monitoring unit 28 are both connected to a comparison unit 30, which is configured for comparing the first and second signals provided by the supply line current monitoring unit 26 and the return line current monitoring unit 28, respectively, and for issuing an alarm signal in case the difference between the first and second signals exceeds a predetermined limit. The ground fault detection apparatus 32 in particular may be configured such that the alarm signal causes a ground fault detection switch 34 to open in order to interrupt the safety chain 10b and to cause the safety relay 18 to switch off in order to stop any operation of the conveyor device.

The components of the ground fault detection apparatus 32, i.e. the supply line current monitoring unit 26, the return line current monitoring unit 28 and the comparison unit 30 may be configured to reliably detect even small differences between the currents flowing through the safety chain supply line 21 and through the safety chain return line 22, respectively. The predetermined limit for detecting a ground fault in particular may correspond to a current difference of 5 mA to 20 mA, in particular to a current difference of 5 mA, 10 mA, 15 mA or 20 mA.

The components of the ground fault detection apparatus 32, i.e. the supply line current monitoring unit 26, the return line current monitoring unit 28 and the comparison unit 30 may be configured to interrupt the safety chain 10b in very short time. The response time, i.e. the time needed for detecting a ground fault and issuing the alarm signal, may be in the range of 10 ms to 500 ms, it in particular may be 250 ms.

At least one of the supply line current monitoring unit 26, the return line current monitoring unit 28 and the comparison unit 30 may comprise at least one microprocessor 27a, 27b, 29a, 29b, 31a, 31b. Employing at least one microprocessor 27a, 27b, 29a, 29b, 31a, 31b allows to easily adapt the supply line current monitoring unit 26, the return line current monitoring unit 28 and/or the comparison unit 30 to the actual needs by changing or amending the program running on the respective microprocessor(s) 27a, 27b, 29a, 29b, 31a, 31b.

In order to enhance the operational reliability, at least one of the supply line current monitoring unit 26, the return line current monitoring unit 28 and the comparison unit 30 may comprise at least two redundant microprocessors 27a, 27b, 29a, 29b, 31a, 31b allowing a second microprocessor 27b, 29b, 31b to take over in case of a failure of a first microprocessors 27a, 29a, 31a.

The supply line current monitoring unit 26, the return line current monitoring unit 28 and the comparison unit 30 may be configured to comply with international standards for electronics in safety application, in particular IEC 61508-1:2010 in order to provide a well-defined level of operational safety.

FIG. 3 illustrates an alternative embodiment of a safety chain 10c. Again, the components which have been discussed with respect to at least one of FIGS. 1 and 2 are designated with the same reference signs and will not be discussed in detail again.

In the embodiment shown in FIG. 3, the safety relay 18 is not connected serially with the safety switches 16a, 16b, 16c. Instead, the safety relay 18 is electrically connected to the comparison unit 30, and the comparison unit 18 is configured to deactivate the safety relay 18 when a ground fault is detected, i.e. when the electrical current flowing though the safety chain supply line 21 differs from the electrical current flowing through the safety chain return line 22 for more than the predetermined limit. The comparison unit 18 is further configured to deactivate the safety relay 18 when no current is flowing through the safety chain 10c, in particular when at least one of the safety switches 16a, 16b, 16c has been opened.

Since in this embodiment, as it is shown in FIG. 3, the safety relay 18 is controlled directly by the comparison unit 30, an additional ground fault detection switch 34 for interrupting the safety chain 10c in case of a ground fault 24 is not necessary. However, a ground fault detection switch 34, which is not shown in FIG. 3, may be optionally provided in order to allow deactivating the safety chain 10c completely in case a ground fault 24 has been detected, which would enhance the safety even further.

FIG. 4 illustrates yet another embodiment of a safety chain 10d. Again, the components which already have been discussed with respect to at least one of FIGS. 1 to 3 are designated with the same reference signs and will not be discussed in detail again.

The embodiment illustrated in FIG. 4 is very similar to the embodiment which has been discussed with reference to FIG. 3. In the embodiment shown in FIG. 4, however, the safety relay 18, which is connected to the comparison unit 30 in the embodiment shown in FIG. 3, is replaced by an electronic safety processor 34. The electronic safety processor 34 is configured to stop any operation of the conveyor when it is triggered by the comparison unit 30. Replacing the electro-mechanical safety relay 18 by an electronic safety processor 36 enhances the operational reliability of the safety chain 10 and provides additional options for reacting on an alarm signal issued by the comparison unit 30.

In order to provide a clear and simple illustration, the embodiments shown in the figures are related to a single safety chain 10a, 10b, 10c, 10d, only. However, it is self-evident that the concept of the invention may be applied easily to each of a plurality of segments of a safety chain 10a, 10b, 10c, 10d, as well. Such a configuration in particular allows specifying and/or locating any interruption of the safety chain 10a, 10b, 10c, 10d and/or a ground fault more specifically. This facilitates to remedy the detected malfunction. The electronic safety processor 34 in particular may be configured to react differently on alarm signals issued by different segments of the safety chain 10a, 10b, 10c, 10d in order to allow a more flexible reaction on detected malfunctions.

### FURTHER EMBODIMENTS

A number of optional features are set out in the following. These features may be realized in particular embodiments, alone or in combination with any of the other features.

In an embodiment at least one of the supply line current monitoring unit, the return line current monitoring unit and the comparison unit comprises at least one microprocessor. Units comprising at least one microprocessor may be adjusted easily to the actual needs by changing and/or amending the program running on the microprocessor. In consequence, the costs for production and maintenance may be reduced.

In an embodiment at least one of the supply line current monitoring unit, the return line current monitoring unit and the comparison unit comprises at least two redundant microprocessors. This enhances the operational safety, since any malfunction of one of the microprocessors may be compensated by the additional microprocessor.

In an embodiment at least one of the supply line current monitoring unit, the return line current monitoring unit and the comparison unit complies with the IEC 61508-1:2010 standard for providing a well-defined and standardized level of safety.

In an embodiment the response time, i.e. the time the apparatus needs for detecting a ground fault and issuing an alarm signal, is in the range of 10 ms to 500 ms, in particular around 250 ms. This ensures a fast detection of ground faults resulting in a fast deactivation of the conveyors drive unit for stopping the conveyor.

In an embodiment the predetermined limit for the difference between the first and second signals corresponds to a range of 5 mA to 20 mA, in particular 5 mA, 10 mA, 15 mA or 20 mA. This ensures a reliable detection even of small ground currents as they may be caused by weak ground faults.

Exemplary embodiments of the invention also include a safety chain, in particular a safety chain of a people conveyor, comprising at last one safety switch/safety circuit and a ground fault detection apparatus according to an exemplary embodiment of the invention. This provides a safety chain which allows for a reliable detection of ground faults.

In an embodiment the safety chain comprises a safety relay sequentially connected with the at last one safety switch/safety circuit. In such a configuration, opening the at last one safety switch/safety circuit interrupts the supply of power to the safety relay resulting in a deactivation of the safety relay. This will interrupt the supply of power delivered to the drive unit of the conveyor. In consequence, opening at least one safety switch/safety circuit will cause the people conveyor to stop.

In an embodiment the safety relay is connected with the comparison unit and is configured to be controlled by an alarm signal issued by the comparison unit. Such a configuration allows a smaller current flowing through the safety chain, as said current does not need to be large enough for holding the safety relay in an activated state. As a result, the safety chain may be produced at reduced costs.

An embodiment comprises an additional electronic safety processor, which is connected with the comparison unit and configured to be controlled by an alarm signal issued by the comparison unit. The electronic safety processor in particular may be configured to interrupt the supply of power delivered to the drive unit of the conveyor. Replacing the safety relay by an electronic safety processor allows enhancing the reliability and reducing the costs, as the electro-magnetic safety relay is replaced by a pure semiconductor device. A programmable electronic safety processor further provides additional options of reacting on the detection of a ground fault/interruption of the safety chain.

An embodiment further comprises an electric power supply, which is configured for providing electrical DC power at a voltage between 12 and 48 V, in particular at a voltage of 12 V, 24 V or 48 V. Electrical DC power at a voltage between 12 and 48 V has proven to be well suited for a reliable operation of the safety chain.

While the invention has been described with reference to exemplary embodiments, it will be understood by those skilled in the art that various changes may be made and equivalents may be substituted for elements thereof without departing from the scope of the invention. In addition many modifications may be made to adopt a particular situation or material to the teachings of the invention without departing from the essential scope thereof. Therefore, it is intended that the invention not be limited to the particular embodiment disclosed, but that the invention include all embodiments falling within the scope of the claims.

### REFERENCES

10a, 10b, 10c, 10d safety chain
12 power supply
14 ground/earth
16a, 16b, 16c safety switch
18 safety relay
20 fuse
21 safety chain supply line
22 safety chain return line
24 ground fault
26 supply line current monitoring unit
27a, 27b microprocessors of the supply line current monitoring unit
28 return line current monitoring unit
27a, 27b microprocessors of the return line current monitoring unit
30 comparison unit
31a, 31b microprocessors of the comparison unit
32 ground fault detection apparatus
34 ground fault detection switch
36 safety processor

1. Ground fault detection apparatus (32) for detecting a ground fault of a safety chain (10b; 10c; 10d), in particular a safety chain (10b; 10c; 10d) of a people conveyor, the ground fault detection apparatus (32) comprising:
a supply line current monitoring unit (26) configured for measuring a current flowing into the safety chain (10b; 10c; 10d) and providing a first signal indicative of the amount of current flowing into the safety chain (10b; 10c; 10d);
a return line current monitoring unit (28) configured for measuring a current flowing out of the safety chain (10b; 10c; 10d) and providing a second signal indicative of the amount of current flowing out of the safety chain (10b; 10c; 10d); and
a comparison unit (30) configured for comparing the first and second signals and issuing an alarm signal in case the difference between the first and second signals exceed a predetermined limit.

2. Ground fault detection apparatus (32) of claim 1, wherein at least one of the supply line current monitoring unit (26), the return line current monitoring unit (28) and the comparison unit (30) comprises at least one microprocessor (27a, 27b, 29a, 29b, 31a, 31b).

3. Ground fault detection apparatus (32) of claim 2, wherein at least one of the supply line current monitoring unit (26), the return line current monitoring unit (28) and the comparison unit (30) comprises at least two redundant microprocessors (27a, 27b, 29a, 29b, 31a, 31b).

4. Ground fault detection apparatus (32) of claim 1, wherein the supply line current monitoring unit (26), the return line current monitoring unit (28) and the comparison unit (30) comply with the IEC 61508-1:2010 standard.

5. Ground fault detection apparatus (32) of claim 1, wherein the time needed for detecting a ground fault is in the range of 10 ms to 500 ms, in particular 250 ms.

6. Ground fault detection apparatus (32) of claim 1, wherein the predetermined limit corresponds to a current difference of 5 mA to 20 mA, in particular 5 mA, 10 mA, 15 mA or 20 mA.

7. Safety chain (10b; 10c; 10d), in particular a safety chain (10b; 10c; 10d) of a people conveyor, comprising:
at last one safety switch (16a, 16b, 16c) or safety circuit; and
a ground fault detection apparatus (32) according to claim 1.

8. Safety chain (10b) of claim 7, further comprising a safety relay (18) which is sequentially connected with the at last one safety switch (16a, 16b, 16c) or safety circuit.

9. Safety chain (10c) of claim 7, further comprising a safety relay (18) which is connected with the comparison unit (30) and configured to be controlled by the alarm signal issued by the comparison unit (30).

10. Safety chain (10d) of claim 7, further comprising an electronic safety processor (36) which is connected with the comparison unit (30) and configured to be controlled by the alarm signal issued by the comparison unit (30).

11. Safety chain (10b; 10c; 10d) of claim 7, further comprising an electric power supply (12) providing electrical DC power at a voltage between 12 V and 48 V, in particular at a voltage of 12 V, 24 V or 48 V.

12. Method of detecting a ground fault of a safety chain (10b; 10c; 10d), in particular a safety chain (10b; 10c; 10d) of a people conveyor, the method comprising:
measuring a current flowing into the safety chain (10b; 10c; 10d) and providing a first signal indicative of the amount of current flowing into the safety chain (10b; 10c; 10d);
measuring a current flowing out of the safety chain (10b; 10c; 10d) and providing a second signal indicative of the amount of current flowing out of the safety chain (10b; 10c; 10d);
comparing the first and second signals and issuing an alarm signal in case the difference between the first and second signals exceeds a predetermined limit.

13. Method of claim 12, comprising the step of switching a safety relay (18) and/or triggering an electronic safety processor (36) in case no current is flowing through the safety chain (10b; 10c; 10d).

14. Method of claim 12, wherein the predetermined limit corresponds to a current difference of 5 mA to 20 mA, in particular 5 mA, 10 mA, 15 mA or 20 mA.

15. Method of claim 12, wherein the time needed for detecting a ground fault is in the range of 100 ms to 500 ms, in particular 250 ms.
